(19) United States
(12) Patent Application Publication
(10) Pub. No.: US 2020/0013861 A1
(43) Pub. Date: Jan. 9, 2020

(54) TUNNELING CONTACTS FOR A TRANSISTOR

(71) Applicant: Intel Corporation, Santa Clara, CA (US)

(72) Inventors: Abhishek A. Sharma, Hillsboro, OR (US); Van H. Le, Beaverton, OR (US); Gilbert W. Dewey, Beaverton, OR (US); Shriram Shivaraman, Hillsboro, OR (US); Tahir Ghani, Portland, OR (US); Jack T. Kavalieros, Portland, OR (US); Cory E. Weber, Hillsboro, OR (US)

(73) Assignee: Intel Corporation, Santa Clara, CA (US)

(21) Appl. No.: 16/489,660

(22) PCT Filed: Mar. 31, 2017
(86) PCT No.: PCT/US2017/025251

§ 371 Date: Aug. 28, 2019

(51) Int. Cl. H01L 29/24; H01L 27/108; H01L 29/786

(52) U.S. Cl. CPC H01L 29/24; H01L 29/7869; H01L 27/10805

(57) ABSTRACT

Substrates, assemblies, and techniques for a backend transistor, where the backend transistor includes a gate, a semiconductor oxide, a source metal and a drain metal, and an insulator between the source metal and the gate and between the drain metal and the gate. The insulator can allow for tunneling between the source metal and/or the drain metal and the semiconductor oxide.

### TECHNICAL FIELD

The present disclosure relates generally to the field of transistors, and more particularly, to tunneling contacts for a transistor.

### BACKGROUND

Most, if not all, logic devices require some type of memory cell such as random access memory (RAM). Dynamic random-access memory (DRAM) is a type of random-access memory that stores each bit of data in a separate capacitor. The capacitor can be charged or discharged and these two states are taken to represent the two values of a bit, (i.e., 1 and 0). DRAM is widely used in digital electronics where low-cost and high-capacity memory is required. One of the largest applications for DRAM is the main memory, or RAM, in modern computers and electronics. The DRAM is typically coupled to a transistor. However, transistors leak a small amount current and can cause the capacitor of the DRAM to discharge and fade.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a simplified block diagram illustrating an embodiment of a portion of an electronic device, in accordance with one embodiment of the present disclosure;

FIG. 2 is a simplified block diagram illustrating an embodiment of a portion of an electronic device, in accordance with one embodiment of the present disclosure;

FIG. 3 is a simplified block diagram illustrating an embodiment of a portion of an electronic device, in accordance with one embodiment of the present disclosure;

FIG. 4 is a simplified block diagram illustrating an embodiment of a portion of an electronic device, in accordance with one embodiment of the present disclosure;

FIG. 5 is a simplified block diagram illustrating an embodiment of a portion of an electronic device, in accordance with one embodiment of the present disclosure;

FIG. 6A is a simplified block diagram illustrating an embodiment of a portion of an electronic device, in accordance with one embodiment of the present disclosure;

FIG. 6B is a simplified block diagram illustrating an embodiment of a portion of an electronic device, in accordance with one embodiment of the present disclosure;

FIG. 6C is a simplified block diagram illustrating an embodiment of a portion of an electronic device, in accordance with one embodiment of the present disclosure;

FIG. 6D is a simplified block diagram illustrating an embodiment of a portion of an electronic device, in accordance with one embodiment of the present disclosure;

FIG. 6E is a simplified block diagram illustrating an embodiment of a portion of an electronic device, in accordance with one embodiment of the present disclosure;

FIG. 6F is a simplified block diagram illustrating an embodiment of a portion of an electronic device, in accordance with one embodiment of the present disclosure;

FIG. 6G is a simplified block diagram illustrating an embodiment of a portion of an electronic device, in accordance with one embodiment of the present disclosure;

FIG. 6H is a simplified block diagram illustrating an embodiment of a portion of an electronic device, in accordance with one embodiment of the present disclosure;

FIG. 6I is a simplified block diagram illustrating an embodiment of a portion of an electronic device, in accordance with one embodiment of the present disclosure;

FIG. 6J is a simplified block diagram illustrating an embodiment of a portion of an electronic device, in accordance with one embodiment of the present disclosure;

FIG. 7 is an interposer implementing one or more of the embodiments disclosed herein; and

FIG. 8 is a computing device built in accordance with an embodiment disclosed herein.

The figures of the drawings are not necessarily drawn to scale, as their dimensions can be varied considerably without departing from the scope of the present disclosure.

### DETAILED DESCRIPTION

The following detailed description sets forth example embodiments of apparatuses, methods, and systems relating to an access transmission gate. Features such as structure(s), function(s), and/or characteristic(s), for example, are described with reference to one embodiment as a matter of convenience; various embodiments may be implemented with any suitable one or more of the described features.

In the following description, various aspects of the illustrative implementations will be described using terms commonly employed by those skilled in the art to convey the substance of their work to others skilled in the art. However, it will be apparent to those skilled in the art that the embodiments disclosed herein may be practiced with only some of the described aspects. For purposes of explanation, specific numbers, materials and configurations are set forth in order to provide a thorough understanding of the illustrative implementations. However, it will be apparent to one skilled in the art that the embodiments disclosed herein may be practiced without the specific details. In other instances, well-known features are omitted or simplified in order not to obscure the illustrative implementations.

Disclosed herein are substrates, assemblies, and techniques for enabling a device that includes one or more tunneling contacts for a transistor. The tunneling contacts can include a layer of an insulator or insulating material that allows for tunneling. The insulator may be tunneling oxide, nitride, or semiconductors that can act as a tunneling insulator or an insulator that allows for tunneling contacts for the source and drain of the transistor. In an example, the insulator with tunneling contacts can be formed by using a layer of tunneling oxide such as titanium oxide, hafnium oxide, silicon dioxide, gallium oxide, tantalum oxide, aluminum oxide etc., a nitride such as silicon nitride, aluminum nitride, etc., or some other material that can function as an insulator and allow for tunneling contacts. This creates a tunneling contact by having the insulator with tunneling contacts between the metal in the gate and the drain and the channel. In a specific example, the source and drain for the transistor can each include a metal above or over an oxide layer.

The tunneling contacts can enable a low off current (loff) while still allowing a high drive current (lon) and can conform to the target currents of both embedded dynamic random-access memory (eDRAM) memory and back end thin film transistor logic. In addition, the tunneling contacts can be used to de-pin the fermi level (or unpin depending on bandgap states) and can result in relatively good quality contacts for the source and drain. In some examples, the tunneling contacts can be located in a backend transistor.

The terms “over,” “above,” “under,” “below,” “between,” and “on” as used herein refer to a relative position of one material layer or component with respect to other layers or components. For example, one layer disposed over, above, or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

Implementations of the embodiments disclosed herein may be formed or carried out on a substrate, such as a non-semiconductor substrate or a semiconductor substrate. In one implementation, the non-semiconductor substrate may be silicon dioxide, inter-layer dielectric composed of silicon dioxide, silicon nitride, titanium oxide and other transition metal oxides. Although a few examples of materials from which the non-semiconducting substrate may be formed are described here, any material that may serve as a foundation upon which a non-semiconductor device may be built falls within the spirit and scope of the embodiments disclosed herein.

In another implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. In other examples, the substrate may be a flexible substrate including 2D materials such as graphene and molybdenum disulphide, organic materials such as pentacene, transparent oxides such as indium gallium zinc oxide poly/amorphous (low temperature of dep) III-V semiconductors and germanium/silicon, and other non-silicon flexible substrates. Although a few examples of materials from which the substrate may be formed are described here, any material that may serve as a foundation upon which a semiconductor device may be built falls within the spirit and scope of the embodiments disclosed herein.

In the following detailed description, reference is made to the accompanying drawings that form a part hereof wherein like numerals designate like parts throughout, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments. For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. As used herein, a “package” and an “IC package” are synonymous. As used herein, the terms “chip” and “die” may be used interchangeably.

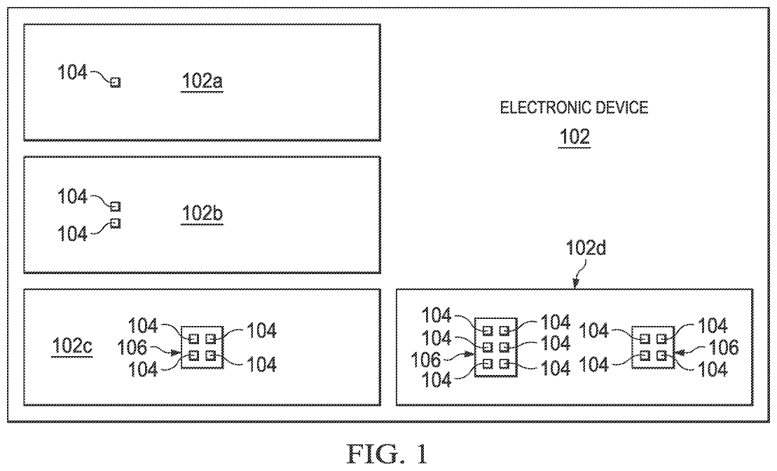

FIG. 1 is a simplified block diagram of an electronic device 100 that includes one or more transistors and arrays in accordance with an embodiment of the present disclosure. Electronic device 100 can be any electronic device that includes memory (e.g., computer, smartphone, laptop, desktop, Internet-of-Things (IoT) device, vehicle electronics, handheld electronic device, personal digital assistant, wearable, household electronics, etc.). Electronic device 100 can include one or more electronic elements 102a-102d. Each electronic element 102a-102d can include one or more transistors 104 and/or one or more transistor arrays 106. Each transistor array 106 can be a systematic arrangement of a plurality of transistors 104, (e.g., in rows and columns).

Transistor 104 can be configured to include a source and drain that from tunneling contacts. In a specific example, the tunneling contacts can be formed by using an insulator that allows for tunneling. The insulator may be a layer of tunneling oxide (e.g., titanium oxide, hafnium oxide, silicon dioxide, gallium oxide, tantalum oxide, aluminum oxide etc.), nitride (e.g., silicon nitride, aluminum nitride, etc.), or some other material that can function as an insulator and allow for tunneling contacts. Transistor 104 can be a transistor or an electronic switch that can be either in an “on” or “off” state and the term “transistor” includes a metal-oxide-semiconductor (MOS), complementary MOS (CMOS), n-channel MOS (NMOS) p-channel MOS (PMOS), MOS field-effect transistors (MOSFET), bipolar junction transistor (BJT), filed effect transistor (FET), finFET, junction gate FET (JFET), insulated gate FET (IGFET), n-channel field effect transistor (NFET) insulated-gate bipolar transistor, or other similar transistor that can be configured to perform the functions, features, and operations disclosed herein. In an example, transistor 104 can be a backend transistor. A backend transistor is a thin filmed transistor above a metal one layer. Backend transistors can allow device functionally to be scaled by stacking memory and logic in the backend. However, most current backend transistors suffer from high contact resistance. This can cause some backend transistors to have a low drive current and degrade the performance of the memory or logic system.

Transistor 104 can be coupled to a capacitive element. The capacitive element may be a memory element such as embedded dynamic random access memory (eDRAM). eDRAM can be integrated on the same die or multi-chip module (MCM) of an application-specific integrated circuit (ASIC) or microprocessor. Embedding memory on the ASIC or microprocessor allows for relatively wider buses and higher operation speeds, and due to much higher density of DRAM in comparison to SRAM, larger amounts of memory can be installed on smaller chips. In another example, transistor 104 can be coupled to a resistive element such as resistive random-access memory (RRAM). In yet another example, transistor 104 can be coupled to some other type of memory or element.

Transistor 104 can be configured such that the source and the drain of the transistor form tunneling contacts by using a thin layer of an insulator that allows for tunneling. The insulator may be tunneling oxide, nitride, or semiconductors that can act as an insulator and allow for tunneling contacts for the source and drain of the transistor. This can enable a low off current (loff) while still allowing a high drive current (lon) and can conform to the target currents of both eDRAM memory and back end thin film transistor logic. In addition, the tunneling contacts can be used to de-pin the fermi level (or unpin depending on bandgap states) and can result in relatively good quality contacts for the source and the drain. In a specific example, transistor 104 can include a gate, a semiconductor oxide above the gate, and a source and a drain above the semiconductor oxide. A source metal and a drain metal can be above the semiconductor oxide and an insulator can be between the source metal and the gate and between the drain metal and the gate.

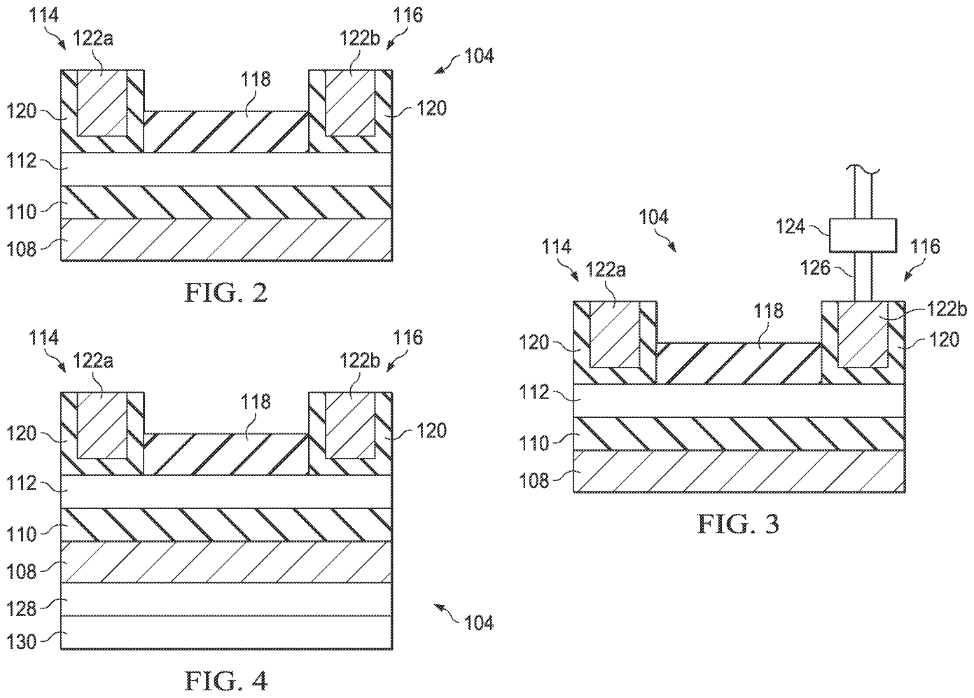

Turning to FIG. 2, FIG. 2 illustrates one embodiment of transistor 104. Transistor 104 can be configured such that the source and the drain of transistor 104 form tunneling contacts. Transistor 104 can include a gate 108, a gate oxide 110, a semiconductor oxide 112, a source 114, a drain 116, and a passivation layer 118. Source 114 can include a source metal 122a. Drain 116 can include a drain metal 122b. An insulator 120 can be between source metal 122a and gate 108 and between drain metal 122b and gate 108. Semiconductor oxide 112 can be configured as a channel. Gate 108 can be configured as a word line. Source 114 can be configured as a source. Drain 116 can be configured as a drain or bit line. Insulator 120 can can be tunneling oxide such as titanium oxide, hafnium oxide, silicon dioxide, gallium oxide, tantalum oxide, aluminum oxide etc., a nitride such as silicon nitride, aluminum nitride, etc., or some other material that can function as an insulator and allow for tunneling contacts from source metal 122a and drain metal 122b to semiconductor oxide 112. In source 114, insulator 120 and source metal 122a can form a source tunneling contact. In drain 116, insulator 120 and drain metal 122b can form a drain tunneling contact.

In the case of an NMOS transistor, when a positive voltage that is greater than the threshold voltage of the NMOS transistor is applied, semiconductor oxide 112 will allow current to flow from source 114 to drain 116. In the case of a PMOS transistor, when a negative voltage that is greater than the threshold voltage of the PMOS transistor is applied, then semiconductor oxide 112 will allow the current to flow. In both the NMOS transistor and the PMOS transistor, when the voltage is below the threshold voltage, the transistor will shut off and the current does not flow. Insulator 120 can act as an insulator and help ensure there is low leakage from source 114 and drain 116. The term “leak” or “leakage” refers to the small amount of current all transistors conduct, even when they are turned off. If the transistor is coupled to a capacitive element, the leakage causes a gradual loss of energy from a capacitive element as the current slowly discharges from the capacitive element. Leakage is currently one of the main factors limiting increased computer processor performance.

Gate 108 can be composed of different metals with various work functions from ranges of about 5.6 eV to about 3.8 eV. More specifically, gate 108 can be composed of layers or bi-layers of tungsten, cobalt, titanium nitride, tantalum nitride, titanium, aluminum, indium tin oxide, tantalum, ruthenium, hafnium, and other similar materials. Gate oxide 110 can be a non-semiconducting substrate and may be composed of silicon oxide, silicon dioxide, inter-layer dielectric composed of silicon dioxide, silicon nitride, titanium oxide, other transition metal oxides, aluminum oxide, sapphire substrates, silicon carbide, or other high-k dielectric materials. The high-k dielectric material may include elements such as hafnium, silicon, oxygen, titanium, tantalum, lanthanum, aluminum, zirconium, barium, strontium, yttrium, lead, scandium, niobium, and zinc. More specifically, the high-k dielectric materials can include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on gate oxide 110 to improve its quality when a high-k material is used.

Semiconductor oxide 112 can be configured as a channel and may be comprised of an indium gallium zinc oxide sulfur alloy, indium gallium zinc oxide, indium oxide, zinc oxide, titanium oxide, zinc oxi-nitride, amorphous silicon, amorphous germanium, polycrystalline silicon, polycrystalline germanium, amorphous or polycrystalline silicon-germanium (with compositions from about five percent (5%) to about eighty percent (80%)), or some other similar semiconducting material. Passivation layer 118 can be comprised of silicon dioxide doped with carbon, thiam oxide, hafnium oxide, a low K dielectric, or some other material that acts as a passivation layer. Source metal 122a and drain metal 122b can each be composed of different metals with various work functions from ranges of about 5.6 eV to about 3.8 eV. More specifically, source metal 122a and drain metal 122b can each be composed of layers or bi-layers of tungsten, cobalt, titanium nitride, tantalum nitride, titanium, aluminum, indium tin oxide, tantalum, ruthenium, hafnium, and other similar materials.

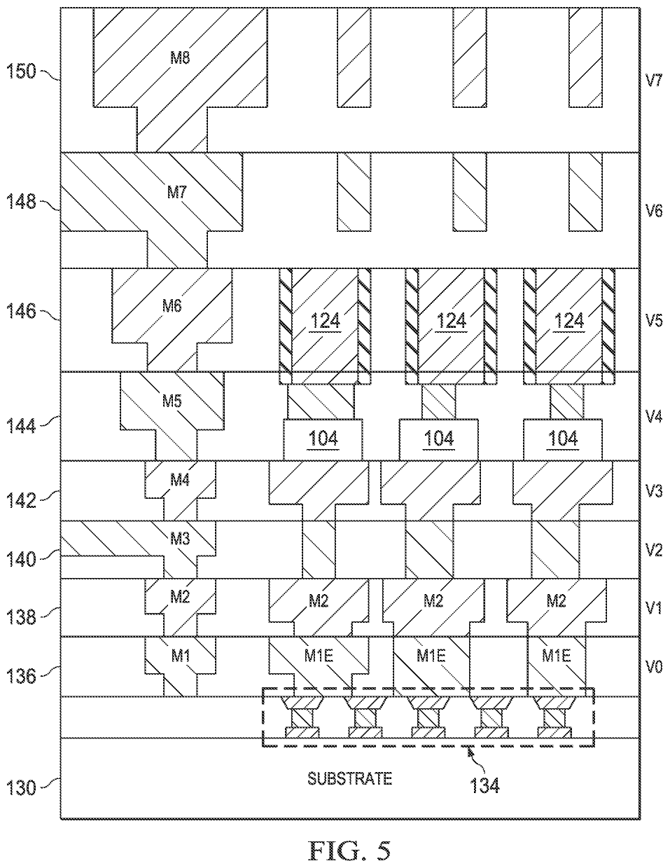

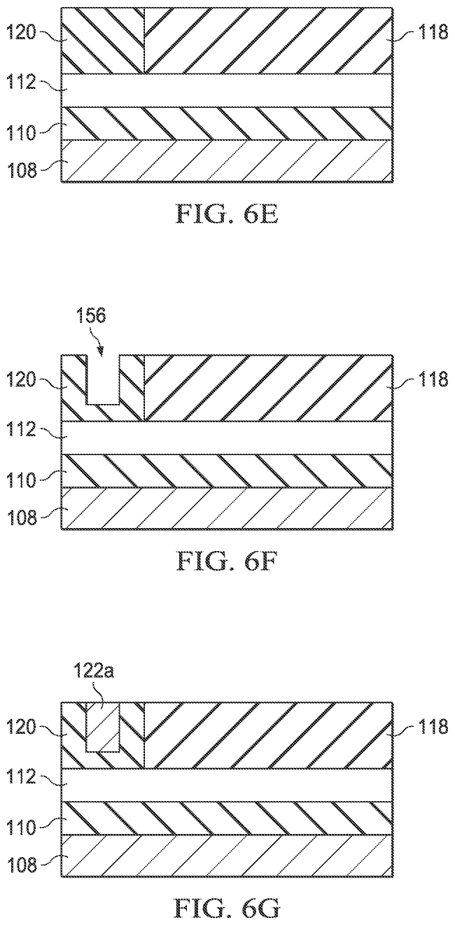

Turning to FIG. 3, FIG. 3 illustrates one embodiment of transistor 104. In a specific implementation, transistor 104 can be coupled to a capacitive element 124 using connector 126. Capacitive element 124 may be a memory element such as RAM or eDRAM. In other examples, capacitive element 124 may not be a capacitive element but a phase change material or resistive element such as a resistive memory element (e.g., RRAM). In yet another example, capacitive element 124 may be magnetoresistive RAM (MRAM), phase change memory, or some other type of memory element. Connector 126 can be configured as metal connections for transistor 104 and may be a metal connection from capacitive element 124 to drain 116. Connector 126 can be part of a metal-2 or metal-3 extended connection, or as illustrated in FIG. 5, part of a metal-4 or metal-5 extended connection.

Transistor 104 can be configured to allow access to capacitive element 124 and charge or change the resistance of capacitive element 124. For example, transistor 104 can be configured to program capacitive element 124, charge or discharge capacitive element 124, deselect or not disturb capacitive element 124, read capacitive element 124, etc. In one implementation, capacitive element 124 can acquire a charge by applying a gate bias to transistor 104 such that current flows through transistor 104 from source 114 to drain 116 and charges a metal terminal of capacitive element 124. When transistor 104 is turned off, the channel resistance is increased significantly and leakage from capacitive element 124 may be reduced as compared to traditional transistors due to the inherent material properties of transistor 104.

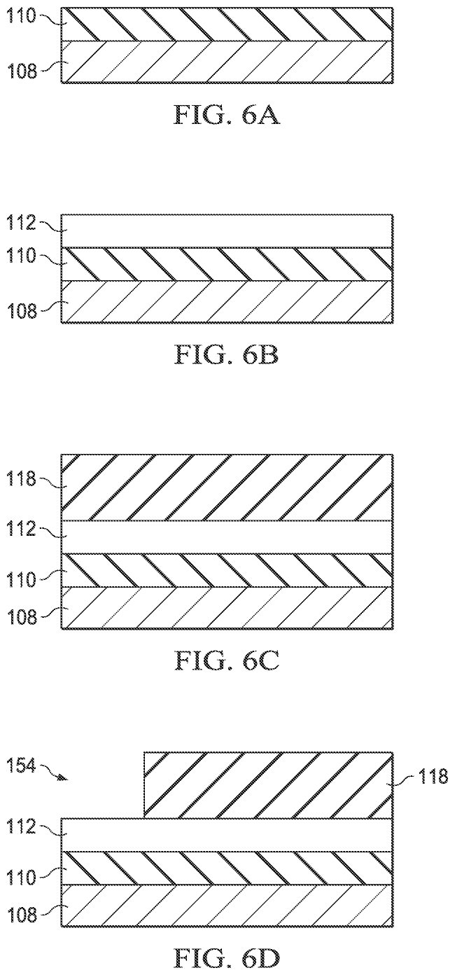

Turning to FIG. 4, FIG. 4 illustrate one embodiment of transistor 104. Transistor 104 can be above or over a silicon based element such as logic circuitry. For example, transistor 104 can be above or over logic 128. Logic 128 can be on, above, or over a base substrate 130. Base substrate 130 may be a silicon based substrate. Logic 128 can include transistors, logic (e.g., adders, registers, etc.), micro-processor circuits for processing data and other circuitry. In an example, logic 128 may be above or over a non-silicon based substrate and may be back ended thin film transistor logic. In another example, logic 128 can communicate with capacitive element 124 through transistor 104 and cause data (or a charge) to be stored in one or more capacitive elements 124.

Scaling of logic devices is typically accomplished by reducing the size of the logic device. One approach is based on increasing the number of logic elements per unit area. To increase the number of logic elements per unit area, the density of dies needs to be increased and additional logic devices need to be fabricated above the silicon. To increase the density of dies in an integrated circuit (IC) package of a particular footprint, one or more transistors 104 may be stacked on top of each other such that instead of fabricating transistor 104 on base substrate 130, transistor 104 can be fabricated above base substrate 130.

Turning to FIG. 5, FIG. 5 illustrates an example of an IC package that includes one embodiment of transistor 104. The IC package can be on base substrate 130 and can include one or more logic elements 134, a first metal layer 136, a second metal layer 138, a third metal layer 140, a fourth metal layer 142, a fifth metal layer 144, a sixth metal layer 146, a seventh metal layer 148, and an eight metal layer 150. Each logic element 134 may be one or more instances of logic 128. As illustrated in FIG. 5, transistor 104 can be in or on fifth metal layer 144 and capacitive element 124 can be in or on sixth metal layer 146. It should be noted that more or less metal layers than illustrated in FIG. 5 may be present. Also, one or more transistors 104 may be in or on one or more different metal layer than the illustrated fifth metal layer 144 and one or more capacitive elements 124 may be in or on one or more different metal layers than the illustrated sixth metal layer 146.

If base substrate 130 is a semiconductor substrate, the semiconductor substrate (and any additional silicon based layers) may be formed using alternate materials, which may or may not be combined with silicon. This includes, but is not limited to, silicon, silicon germanium, germanium, indium antimonide, lead telluride, indium arsenide, indium phosphide, gallium arsenide, indium gallium arsenide, gallium antimonide, or other combinations of group III-V or group IV materials. In other examples, the substrate of any layer may be a flexible substrate including 2D materials such as graphene and molybdenum disulfide, organic materials such as pentacene, transparent oxides such as indium gallium zinc oxide poly/amorphous (low temperature of dep) III-V semiconductors and germanium/silicon, and other non-silicon flexible substrates.

In an example, a plurality of electrical components can include one or more transistors 104 and/or one or more arrays 106 of transistors 104. In addition, a plurality of transistors, such as MOSFET or simply MOS transistors, can include one or more transistors 104 and may be fabricated on base substrate 130. In various embodiments, the MOS transistors may be planar transistors, nonplanar transistors, or a combination of both. Nonplanar transistors include FinFET transistors such as double-gate transistors and tri-gate transistors, and wrap-around or all-around gate transistors such as nanoribbon and nanowire transistors. Although the implementations described herein may illustrate only planar transistors, it should be noted that various embodiments may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer is formed on the gate dielectric layer and may consist of at least one P-type work function metal or N-type work function metal, depending on whether the transistor is to be a PMOS or an NMOS transistor. In some implementations, the gate electrode layer may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a work function that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a work function that is between about 3.9 eV and about 4.2 eV.

In some implementations, when viewed as a cross-section of the transistor along the source-channel-drain direction, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In an alternate implementation, a plurality of spacer pairs may be used, for instance, two pairs, three pairs, or four pairs of sidewall spacers may be formed on opposing sides of the gate stack.

Source and drain regions can be formed within base substrate 130 adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations, the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. And in further embodiments, one or more layers of metal and/or metal alloys may be used to form the source and drain regions.

One or more interlayer dielectrics (ILD) can be deposited over the MOS transistors. The ILD layers may be formed using dielectric materials known for their applicability in integrated circuit structures, such as low-k dielectric materials. Examples of dielectric materials that may be used include, but are not limited to, silicon dioxide, carbon doped oxide, silicon nitride, organic polymers such as perfluorocyclobutane or polytetrafluoroethylene, fluorosilicate glass, and organosilicates such as silsesquioxane, siloxane, or organosilicate glass. The ILD layers may include pores or air gaps to further reduce their dielectric constant.

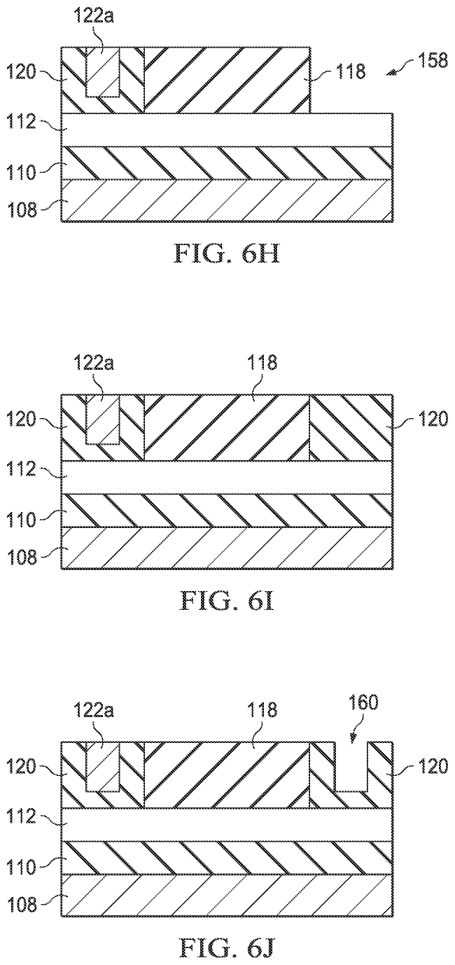

Turning to FIG. 6A, FIG. 6A illustrates a simplified block diagram of an early stage in the formation of transistor 104 in accordance with an embodiment of the present disclosure. As illustrated in FIG. 6A, gate oxide 110 can be deposited on gate 108. Gate oxide 110 may be deposited using a spin-on deposition from slurry, sputtering, chemical vapor deposition (CVD), thermal vacuum deposition (TVD), atomic layer deposition (ALD), or any combination, or some other form of deposition that can deposit gate oxide 110 on gate 108. Gate 108 may be about one (1) nanometers to about twenty (20) nanometers in thickness. Gate oxide 110 may also be about 1 nanometers to about 20 nanometers in thickness.

Turning to FIG. 6B, FIG. 6B illustrates a simplified block diagram of an early stage in the formation of transistor 104 in accordance with an embodiment of the present disclosure. In an example, semiconductor oxide 112 can be deposited on gate oxide 110. Semiconductor oxide 112 may be deposited using a spin-on deposition from slurry, sputtering, CVD, TVD, ALD, or any combination, or some other form of deposition that can deposit semiconductor oxide 112 on gate oxide 110. Semiconductor oxide 112 can be comprised of a material with a high K dielectric such as Hafnium(IV) oxide, silicon dioxide, etc. Semiconductor oxide 112 may be about 1 nanometer to about 20 nanometers in thickness.

Turning to FIG. 6C, FIG. 6C illustrates a simplified block diagram of an early stage in the formation of transistor 104 in accordance with an embodiment of the present disclosure. In an example, passivation layer 118 can be deposited on semiconductor oxide 112. Passivation layer 118 may be deposited using a spin-on deposition from slurry, sputtering, CVD, TVD, ALD, or any combination, or some other form of deposition that can deposit passivation layer 118 on semiconductor oxide 112. Passivation layer 118 may be about 1 nanometer to about 20 nanometers in thickness.

Turning to FIG. 6D, FIG. 6D illustrates a simplified block diagram of a stage in the formation of transistor 104 in accordance with an embodiment of the present disclosure. As illustrated in FIG. 6C, passivation layer 118 can be etched to create a source recess 154. Source recess 154 can extend down to semiconductor oxide 112.

Turning to FIG. 6E, FIG. 6E illustrates a simplified block diagram of a stage in the formation of transistor 104 in accordance with an embodiment of the present disclosure. As illustrated in FIG. 6E, insulator 120 can be deposited in source recess 154. Insulator 120 may be deposited using a spin-on deposition from slurry, sputtering, CVD, TVD, ALD, or any combination, or some other form of deposition that can deposit insulator 120 in source recess 154 and on semiconductor oxide 112. Insulator 120 may be about 1 nanometer to about 20 nanometers in thickness. In an example, the stage in the formation of transistor 104 illustrated in FIG. 6E may be skipped.

Turning to FIG. 6F, FIG. 6F illustrates a simplified block diagram of a stage in the formation of transistor 104 in accordance with an embodiment of the present disclosure. As illustrated in FIG. 6F, insulator 120 can be etched to create a source metal recess 156. Source metal recess 156 can extend into insulator 120. In an example, if the stage in the formation of transistor 104 illustrated in FIG. 6E is skipped, then insulator 120 may be deposited in source recess 154 as illustrated in FIG. 6F.

Turning to FIG. 6G, FIG. 6G illustrates a simplified block diagram of a stage in the formation of transistor 104 in accordance with an embodiment of the present disclosure. As illustrated in FIG. 6G, source metal 122a can be deposited in source metal recess 156. Source metal 122a may be deposited using a spin-on deposition from slurry, sputtering, CVD, TVD, ALD, or any combination, or some other form of deposition that can deposit source metal 122a in source metal recess 156 and on insulator 120. Source metal 122a may be about 1 nanometer to about 20 nanometers in thickness.

Turning to FIG. 6H, FIG. 6H illustrates a simplified block diagram of a stage in the formation of transistor 104 in accordance with an embodiment of the present disclosure. As illustrated in FIG. 6H, passivation layer 118 can be etched to create a drain recess 158. Drain recess 158 can extend down to semiconductor oxide 112.

Turning to FIG. 6I, FIG. 6I illustrates a simplified block diagram of a stage in the formation of transistor 104 in accordance with an embodiment of the present disclosure. As illustrated in FIG. 6I, insulator 120 can be deposited in drain recess 158. Insulator 120 may be deposited using a spin-on deposition from slurry, sputtering, CVD, TVD, ALD, or any combination, or some other form of deposition that can deposit insulator 120 in drain recess 158 and on semiconductor oxide 112. Insulator 120 may be about 1 nanometer to about 20 nanometers in thickness. In an example, the stage in the formation of transistor 104 illustrated in FIG. 6I may be skipped.

Turning to FIG. 6J, FIG. 6J illustrates a simplified block diagram of a stage in the formation of transistor 104 in accordance with an embodiment of the present disclosure. As illustrated in FIG. 6J, insulator 120 can be etched to create a drain metal recess 160. Drain metal recess 160 can extend into insulator 120. Drain metal 122b can be deposited in drain metal recess 160 to create transistor 104 illustrated in FIG. 2. Drain metal 122b may be deposited using a spin-on deposition from slurry, sputtering, CVD, TVD, ALD, or any combination, or some other form of deposition that can deposit drain metal 122b in drain metal recess 160 and on insulator 120. Drain metal 122b may be about 1 nanometer to about 20 nanometers in thickness. In an example, if the stage in the formation of transistor 104 illustrated in FIG. 6I is skipped, then insulator 120 may be deposited in drain recess 158 as illustrated in FIG. 6J.

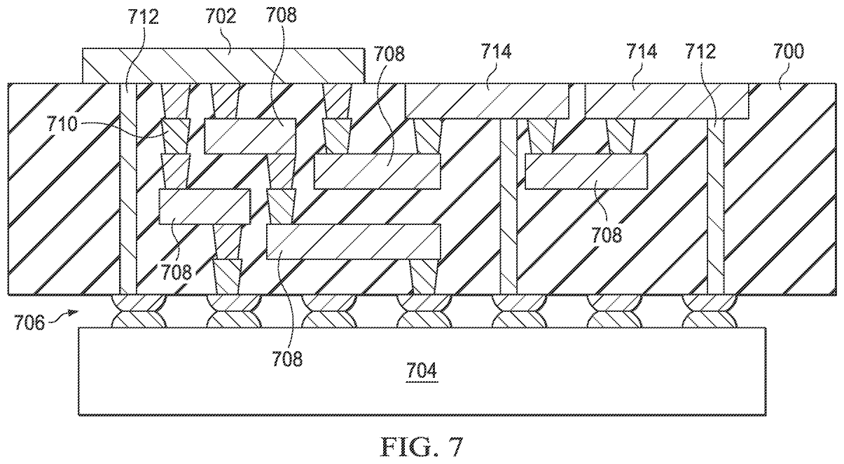

Turning to FIG. 7, FIG. 7 illustrates an interposer 700 that can include or interact with one or more embodiments disclosed herein. The interposer 700 is an intervening substrate used to bridge a first substrate 702 to a second substrate 704. The first substrate 702 may be, for instance, an integrated circuit die. The second substrate 704 may be, for instance, a memory module, a computer motherboard, or another integrated circuit die. Generally, the purpose of an interposer 700 is to spread a connection to a wider pitch or to reroute a connection to a different connection. For example, an interposer 700 may couple an integrated circuit die to a ball grid array (BGA) 706 that can subsequently be coupled to the second substrate 704. In some embodiments, the first and second substrates 702/704 are attached to opposing sides of the interposer 700. In other embodiments, the first and second substrates 702/704 are attached to the same side of the interposer 700. And in further embodiments, three or more substrates are interconnected by way of the interposer 700.

The interposer 700 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer may include metal interconnects 708 and vias 710, including but not limited to through-silicon vias (TSVs) 712. The interposer 700 may further include embedded devices 714, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 700. In accordance with various embodiments, apparatuses or processes disclosed herein may be used in the fabrication of interposer 700.

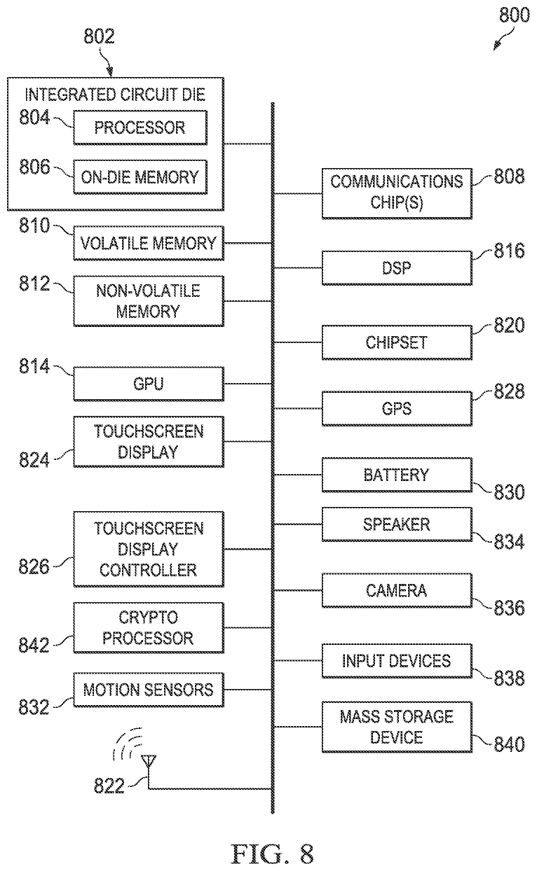

Turning to FIG. 8, FIG. 8 illustrates a computing device 800 in accordance with various embodiments. The computing device 800 may include a number of components. In one embodiment, these components are attached to one or more motherboards. In an alternate embodiment, some or all of these components are fabricated onto a single system-on-a-chip (SoC) die. The components in the computing device 800 include, but are not limited to, an integrated circuit die 802 and at least one communications logic unit 808. In some implementations, the communications logic unit 808 is fabricated within the integrated circuit die 802 while in other implementations the communications logic unit 808 is fabricated in a separate integrated circuit chip that may be bonded to a substrate or motherboard that is shared with or electronically coupled to the integrated circuit die 802. The integrated circuit die 802 may include a CPU 804 as well as on-die memory 806, often used as cache memory, that can be provided by technologies such as embedded DRAM (eDRAM) or spin-transfer torque memory (STTM or STT-MRAM).

Computing device 800 may include other components that may or may not be physically and electrically coupled to the motherboard or fabricated within an SoC die. These other components include, but are not limited to, volatile memory 810 (e.g., DRAM), non-volatile memory 812 (e.g., ROM or flash memory), a graphics processing unit 814 (GPU), a digital signal processor 816, a crypto processor 842 (a specialized processor that executes cryptographic algorithms within hardware), a chipset 820, an antenna 822, a display or a touchscreen display 824, a touchscreen controller 826, a battery 828 or other power source, a power amplifier (not shown), a voltage regulator (not shown), a global positioning system (GPS) device 828, a compass 830, a motion coprocessor or sensors 832 (that may include an accelerometer, a gyroscope, and a compass), a speaker 834, a camera 836, user input devices 838 (such as a keyboard, mouse, stylus, and touchpad), and a mass storage device 840 (such as hard disk drive, compact disk (CD), digital versatile disk (DVD), and so forth).

The communications logic unit 808 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communications logic unit 808 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communications logic units 808. For instance, a first communications logic unit 808 may be dedicated to shorter range wireless communications such as Wi-Fi and Bluetooth and a second communications logic unit 808 may be dedicated to longer range wireless communications such as GPS, EDGE, GPRS, CDMA, WiMAX, LTE, Ev-DO, and others.

The processor 804 of the computing device 800 can communicate with one or more devices that are formed in accordance with various embodiments. The term “processor” may refer to any device or portion of a device that processes electronic data from registers and/or memory to transform that electronic data into other electronic data that may be stored in registers and/or memory.

The communications logic unit 808 may also include one or more devices, such as transistors or metal interconnects, that are in communication with various ones of the embodiments disclosed herein. In further embodiments, another component housed within the computing device 800 may contain one or more devices, such as transistors or metal interconnects, that are formed in accordance with implementations of the embodiments disclosed herein.

In various embodiments, the computing device 800 may be a laptop computer, a netbook computer, a notebook computer, an ultrabook computer, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 800 may be any other electronic device that processes data.

The above description of illustrated implementations, including what is described in the Abstract, is not intended to be exhaustive or to limit the scope of the disclosure to the precise forms disclosed. While specific implementations of, and examples for, the embodiments disclosed herein are described herein for illustrative purposes, various equivalent modifications are possible within the scope of the disclosure, as those skilled in the relevant art will recognize.

### OTHER NOTES AND EXAMPLES

Example 1 is an apparatus including a transistor, where the transistor includes a gate, a semiconductor oxide, a source metal and a drain metal, and an insulator between the source metal and the gate and between the drain metal and the gate.

In Example 2, the subject matter of Example 1 can optionally include where the insulator is on a sidewall and bottom surface of the source metal and the drain metal but not on a top surface of the source metal and the drain metal.

In Example 3, the subject matter of any one of Examples 1 and 2 can optionally include where the insulator allows for tunneling between the source metal and the semiconductor oxide.

In Example 4, the subject matter of any one of Examples 1-3 can optionally include where a gate oxide layer is between the gate and the semiconductor oxide.

In Example 5, the subject matter of any one of Examples 1-4 can optionally include where the transistor is above a logic element.

In Example 6, the subject matter of any one of Examples 1-5 can optionally include where the insulator is on the semiconductor oxide.

In Example 7, the subject matter of any one of Examples 1-6 can optionally include where the transistor is coupled to a capacitive element.

In Example 8, the subject matter of any one of Examples 1-7 can optionally include where the capacitive element is embedded dynamic random access memory.

In Example 9, a method for creating a tunneling contact for a transistor can include depositing a gate oxide layer on a gate, depositing a semiconductor oxide layer on the gate oxide layer, depositing a passivation layer on the semiconductor oxide layer, etching the passivation layer to create a source cavity, depositing an insulator in the source cavity and on the semiconductor oxide layer, etching the insulator to create a source metal cavity, and depositing a source metal in the source metal cavity to create a source for a transistor.

In Example 10, the subject matter of Example 9 can optionally include etching the passivation layer to create a drain cavity, depositing the insulator in the drain cavity and on the semiconductor oxide layer, etching the insulator to create a drain metal cavity, and depositing a drain metal in the drain metal cavity to create a drain for the transistor.

In Example 11, the subject matter of any one of Examples 9 and 10 can optionally include where the transistor is on a non-silicon substrate.

In Example 12, the subject matter of any one of Examples 9-11 can optionally include where the transistor is above a logic element.

In Example 13, the subject matter of any one of Examples 9-12 can optionally include where the transistor is coupled to a capacitive element.

In Example 14, the subject matter of any one of Examples 9-13 can optionally include where the transistor is coupled to embedded dynamic random access memory.

In Example 15, the subject matter of any one of Examples 9-14 can optionally include where a gate oxide layer is between the gate and the semiconductor oxide.

Example 16 is a computing device including a processor mounted on a substrate, a communications logic unit within the processor, a memory within the processor, a graphics processing unit within the computing device, an antenna within the computing device, a display on the computing device, a battery within the computing device, a power amplifier within the processor, and a voltage regulator within the processor. The memory can be coupled to a transistor and the transistor can include a gate, a semiconductor oxide, a source metal and a drain metal, and an insulator between the source metal and the gate and between the drain metal and the gate.

In Example 17 the subject matter of Example 16 can optionally include where the insulator is on a sidewall and bottom surface of the source metal and the drain metal but not on a top surface of the source metal and the drain metal.

In Example 18 the subject matter of any one of Examples 16 and 17 can optionally include where the insulator allows for tunneling between the source metal and the semiconductor oxide.

In Example 19, the subject matter of any one of the Examples 16-18 can optionally include where the backend transistor is above a logic element.

In Example 20, the subject matter of any one of the Examples 15-19 can optionally include where a gate oxide layer is between the gate and the semiconductor oxide.

Example 21 is an integrated circuit (IC) assembly including a non-silicon substrate, a transistor on top of the non-silicon substrate, where the transistor includes a gate, a semiconductor oxide, a source metal and a drain metal, and an insulator between the source metal and the gate and between the drain metal and the gate.

In Example 22, the subject matter of Example 21 can optionally include where the insulator is on a sidewall and bottom surface of the source metal and the drain metal but not on a top surface of the source metal and the drain metal.

In Example 23, the subject matter of any one of the Examples 21 and 22-23 can optionally include where the insulator allows for tunneling between the source metal and the semiconductor oxide.

In Example 24, the subject matter of any one of the Examples 21-23 can optionally include where the transistor is on a non-silicon substrate.

In Example 25, the subject matter of any one of the Examples 22-24 can optionally include where a gate oxide layer is between the gate and the semiconductor oxide.

1. An apparatus, comprising:
a backend transistor, wherein the backend transistor includes:
a gate,
a semiconductor oxide,
a source metal,
a drain metal, and
an insulator between the source metal and the gate, and between the drain metal and the gate.

2. The apparatus of claim 1, wherein the insulator is on a sidewall and a bottom surface of the source metal and the drain metal, but not on a top surface of the source metal and the drain metal.

3. The apparatus of claim 2, wherein the insulator allows for tunneling between the source metal and the semiconductor oxide.

4. The apparatus of claim 1, wherein a gate oxide layer is between the gate and the semiconductor oxide.

5. The apparatus of claim 1, wherein the backend transistor is above a logic element.

6. The apparatus of claim 1, wherein the insulator is on the semiconductor oxide.

7. The apparatus of claim 1, wherein the backend transistor is coupled to a capacitive element.

8. The apparatus of claim 7, wherein the capacitive element is part of an embedded dynamic random access memory.

9-15. (canceled)

16. A computing device, comprising:
a processor mounted on a substrate;
a memory within the processor;
wherein the memory is coupled to a backend transistor, and the backend transistor includes:
a gate;
a semiconductor oxide;
a source metal;
a drain metal; and
an insulator between the source metal and the gate and between the drain metal and the gate.

17. The computing device of claim 16, wherein the insulator is on a sidewall and bottom surface of the source metal and the drain metal but not on a top surface of the source metal and the drain metal.

18. The computing device of claim 16, wherein the insulator allows for tunneling between the source metal and the semiconductor oxide.

19. The computing device of claim 16, wherein the backend transistor is above a logic element.

20. The computing device of claim 16, wherein a gate oxide layer is between the gate and the semiconductor oxide.

21. An integrated circuit (IC) assembly, comprising:
a non-silicon substrate; and
a backend transistor on top of the non-silicon substrate, wherein the backend transistor includes:
a gate,
a semiconductor oxide,
a source metal,
a drain metal, and
an insulator between the source metal and the gate, and between the drain metal and the gate.

22. The IC assembly of claim 21, wherein the insulator is on a sidewall and bottom surface of the source metal and the drain metal, but not on a top surface of the source metal and the drain metal.

23. The IC assembly of claim 21, wherein the insulator allows for tunneling between the source metal and the semiconductor oxide.

24. The IC assembly of claim 21, wherein the backend transistor is on a non-silicon substrate.

25. The IC assembly of claim 21, wherein a gate oxide layer is between the gate and the semiconductor oxide.
